(19) United States
(12) Patent Application Publication
(10) Pub. No.: US 2026/0006949 A1
(43) Pub. Date: Jan. 1, 2026

(54) LIGHT EMITTING APPARATUS

(71) Applicant: SONY GROUP CORPORATION, TOKYO (JP)

(72) Inventor: NAOKI HIRAO, TOKYO (JP)

(21) Appl. No.: 18/880,589

(22) PCT Filed: Jun. 1, 2023
(86) PCT No.: PCT/JP2023/020554

§ 371 Date: Jan. 2, 2025

(30) Foreign Application Priority Data
Jul. 26, 2022 (JP) 2022-118567

(51) Int. Cl. H10H 20/819; H10H 20/825; H10H 20/841; H10H 20/855

(52) U.S. Cl. CPC H10H 20/819; H10H 20/841; H10H 20/855; H10H 20/825

(57) ABSTRACT

A light emitting apparatus of the present disclosure includes: a first light emitting unit including: a first crystalline layer provided on a light extraction surface side; a second crystalline layer; and a light emitting layer disposed between the first crystalline layer and the second crystalline layer, at least a portion of a light extraction surface of the first crystalline layer being an optical functional surface, the optical functional surface having a light collecting effect; and an optical unit including at least one optical member having a light collecting effect, the optical unit being opposed to the light extraction surface side of the first light emitting unit.

### TECHNICAL FIELD

The present disclosure relates to a light emitting apparatus usable for an LED (Light Emitting Diode) or the like.

### BACKGROUND ART

For a display apparatus including a self-luminous light source such as a micro LED array, enhancement of a light extraction efficiency is a very important factor for enhancing the power efficiency of the display apparatus to improve merchantability. In particular, in a case where the light source is used as a light source to be used in an AR (Augmented Reality) device, it is very important to efficiently deliver a light beam from the light source to a designated finite light-receiving region. Accordingly, with use of an optical element such as a lens, orientation characteristics may be controlled to collect light so that the light is efficiently delivered. For example, there are a proposed method, etc. in which a microlens array is disposed with respect to a light emitting element such as an LED (see, for example, PTLs 1 to 3).

### CITATION LIST

### Patent Literature

PTL 1: Japanese Unexamined Patent Application Publication No. 2019-192888

PTL 2: Japanese Unexamined Patent Application Publication No. 2002-49326

PTL 3: Japanese Unexamined Patent Application Publication No. 2021-4926

### SUMMARY OF THE INVENTION

For example, for a method in which a microlens array is disposed with respect to an LED array, it is difficult to narrow an arrangement pitch of the LED. It is also difficult to sufficiently improve the light extraction efficiency.

It is desirable to provide a light emitting apparatus enabling an improved light extraction efficiency.

A light emitting apparatus according to an embodiment of the present disclosure includes: a first light emitting unit including: a first crystalline layer provided on a light extraction surface side; a second crystalline layer; and a light emitting layer disposed between the first crystalline layer and the second crystalline layer, at least a portion of a light extraction surface of the first crystalline layer being an optical functional surface, the optical functional surface having a light collecting effect; and an optical unit including at least one optical member having a light collecting effect, the optical unit being opposed to the light extraction surface side of the first light emitting unit.

In the light emitting apparatus according to the embodiment of the present disclosure, at least a portion of a light extraction surface of a first crystalline layer has a light collecting effect and an optical unit opposed to a light extraction surface side of a first light emitting unit has a light collecting effect.

### BRIEF DESCRIPTION OF DRAWING

FIG. 1 is a schematic cross-sectional view of a first configuration example of a light emitting apparatus according to an embodiment of the present disclosure.

FIG. 2 is a schematic cross-sectional view of a second configuration example of a light emitting apparatus according to an embodiment.

FIG. 3 is a schematic cross-sectional view of a third configuration example of a light emitting apparatus according to an embodiment.

FIG. 4 is a schematic cross-sectional view of a fourth configuration example of a light emitting apparatus according to an embodiment.

FIG. 5 is a schematic cross-sectional view of a fifth configuration example of a light emitting apparatus according to an embodiment.

FIG. 6 is a schematic cross-sectional view of a sixth configuration example of a light emitting apparatus according to an embodiment.

FIG. 7 is a schematic cross-sectional view of a seventh configuration example of a light emitting apparatus according to an embodiment.

FIG. 8 is a schematic cross-sectional view of an eighth configuration example of a light emitting apparatus according to an embodiment.

FIG. 9 is a schematic cross-sectional view of a ninth configuration example of a light emitting apparatus according to an embodiment.

FIG. 10 is a schematic cross-sectional view of a tenth configuration example of a light emitting apparatus according to an embodiment.

FIG. 11 is a schematic cross-sectional view of an eleventh configuration example of a light emitting apparatus according to an embodiment.

FIG. 12 is a schematic cross-sectional view of a twelfth configuration example of a light emitting apparatus according to an embodiment.

FIG. 13 is a schematic cross-sectional view of a thirteenth configuration example of a light emitting apparatus according to an embodiment.

FIG. 14 is a schematic cross-sectional view of a fourteenth configuration example of a light emitting apparatus according to an embodiment.

FIG. 15 is a schematic cross-sectional view of a fifteenth configuration example of a light emitting apparatus according to an embodiment.

FIG. 16 is a schematic cross-sectional view of a sixteenth configuration example of a light emitting apparatus according to an embodiment.

FIG. 17 is a schematic cross-sectional view of a seventeenth configuration example of a light emitting apparatus according to an embodiment.

FIG. 18 is a schematic cross-sectional view of an eighteenth configuration example of a light emitting apparatus according to an embodiment.

FIG. 19 is a schematic cross-sectional view of a nineteenth configuration example of a light emitting apparatus according to an embodiment.

FIG. 20 is a schematic cross-sectional view of a twentieth configuration example of a light emitting apparatus according to an embodiment.

FIG. 21 is a schematic cross-sectional view of a twenty-first configuration example of a light emitting apparatus according to an embodiment.

FIG. 22 is a diagram of assistance in explaining an example of respective specific materials of units of the light emitting apparatuses according to the nineteenth to twenty-first configuration examples.

FIG. 23 is a schematic cross-sectional view of a configuration example of a light emitting apparatus according to a comparative example.

FIG. 24 is a schematic cross-sectional view of a configuration example of a light emitting apparatus according to an embodiment.

FIG. 25 is a schematic cross-sectional view of a configuration example of a light emitting apparatus according to an embodiment.

FIG. 26 is a diagram of assistance in explanation about a combined focal position of an optical functional surface of a first light emitting unit and an optical unit in the configuration example illustrated in FIG. 25.

FIG. 27 is a schematic cross-sectional view of a configuration example of a light emitting apparatus according to an embodiment.

FIG. 28 is a diagram of assistance in explanation about a combined focal position of an optical functional surface of a first light emitting unit and an optical unit in the configuration example illustrated in FIG. 27

### MODES FOR CARRYING OUT THE INVENTION

In the following, some embodiments of the present disclosure are described in detail with reference to the drawings. It is to be noted that description is made in the following order.

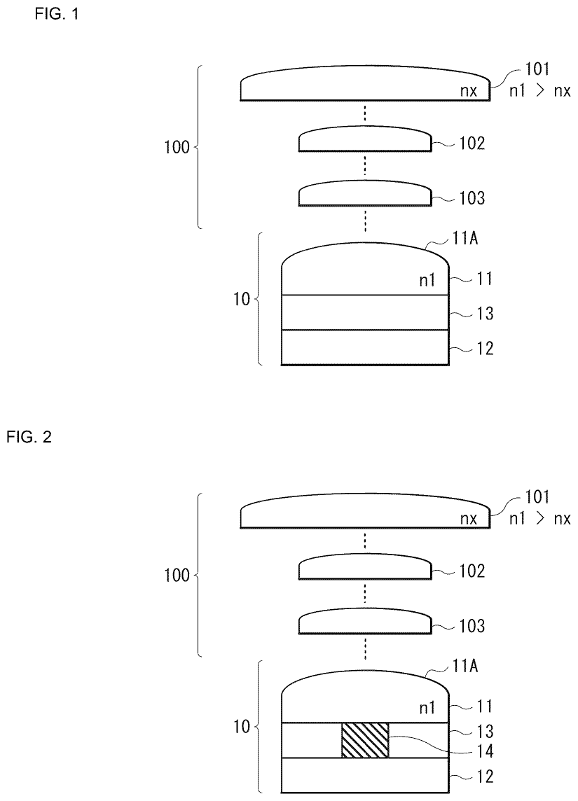

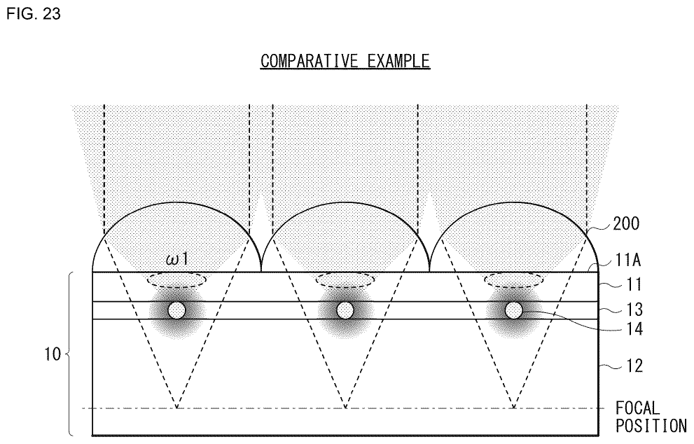

1. Embodiment
1. 1 Configuration Examples (FIG. 1 to FIG. 22)
1. 2 Workings and Effects (FIG. 23 to FIG. 28)

2. Other Embodiments

### 1. EMBODIMENT

### 1.1 Configuration Examples

### First Configuration Example

FIG. 1 schematically illustrates a first configuration example of a light emitting apparatus according to an embodiment of the present disclosure.

The light emitting apparatus according to the first configuration example includes a first light emitting unit 10 and an optical unit 100 opposed to a light extraction surface side of the first light emitting unit 10.

The first light emitting unit 10 includes a first crystalline layer 11, a second crystalline layer 12, and a light emitting layer 13 disposed between the first crystalline layer 11 and the second crystalline layer 12. The first light emitting unit 10 is, for example, a P-based or GaN-based red LED. The first light emitting unit 10 may also be a GaN-based green LED or a GaN-based blue LED.

The first crystalline layer 11 is provided on the light extraction surface side. In the light emitting apparatus according to the first configuration example, a surface 11A of the first crystalline layer 11 is a light extraction surface. At least a portion of the light extraction surface of the first crystalline layer 11 is an optical functional surface having a light collecting effect. The optical functional surface may be, for example, a spherical lens structure or an aspheric lens structure. The first crystalline layer 11 is, for example, an epitaxial layer (a semiconductor layer). The first crystalline layer 11 is, for example, an AlGaInP layer doped with Mg, Si, Zn, or the like. The first crystalline layer 11 may also be, for example, a GaN layer doped with Mg, Si, or the like.

The second crystalline layer 12 is provided opposite the light extraction surface with the light emitting layer 13 in between. The second crystalline layer 12 is, for example, an epitaxial layer (a semiconductor layer). The second crystalline layer 12 is, for example, an AlGaInP layer doped with Mg, Si, Zn, or the like. The second crystalline layer 12 may also be, for example, a GaN layer doped with Mg, Si, or the like.

The light emitting layer 13 emits, for example, red, green, or blue light. The light emitting layer 13 is, for example, a GaInP layer or a GaInN layer.

The optical unit 100 includes at least one optical member having a light collecting effect. In the configuration example in FIG. 1, a first optical member 101, a second optical member 102, and a third optical member 103 are provided as optical members in sequence from the farthest position from the first light emitting unit 10. The optical member of the optical unit 100 may be, for example, SiN or TiO₂. A refractive index nx of the first optical member 101 disposed at the farthest position from the first light emitting unit 10 is lower than a refractive index n1 of the first crystalline layer 11 in which the optical functional surface is formed (n1>nx).

### Workings and Effects of First Configuration Example

In the light emitting apparatus according to the first configuration example, the surface 11A of the first crystalline layer 11 provided on the light extraction surface side is the optical functional surface having a light collecting effect. Since a difference in refractive index between the first crystalline layer 11 and the light emitting layer 13 is extremely small, Bragg reflection is unlikely to occur. Further, a high light extraction efficiency is expectable as it is expectable that the first crystalline layer 11 has an LED-specific large refractive index. In order to cause the optical functional surface of the first crystalline layer 11 to produce a sufficient light collecting performance, it is more preferable that a focal position of the optical functional surface be closer to the light emitting layer 13.

However, since the first crystalline layer 11 is adjacent to the light emitting layer 13, the focal position through the optical functional surface of the first crystalline layer 11 is unlikely to be placed on the light emitting layer 13 and the efficiency is not increased. For example, if a curvature radius of a lens surface serving as the optical functional surface is reduced to shorten a focal length, a bore of the optical functional surface becomes small, resulting in a small solid angle and a low efficiency. The solid angle effectively contributes to collecting light. Contrarily, if the curvature radius is increased, the focal position becomes distant from the light emitting layer 13 with the light collecting performance reduced. As a result, the efficiency is lowered.

Accordingly, in the light emitting apparatus according to an embodiment, the optical unit 100 is opposed to the light extraction surface side of the first light emitting unit 10, which causes the combined focal position of the optical functional surface of the first light emitting unit 10 and the optical unit 100 to be close to the light emitting layer 13. This improves the light extraction efficiency. Moreover, in a case where the light emitting apparatus is arrayed, it is possible to narrow an arrangement pitch of the first light emitting unit 10.

### Second Configuration Example

FIG. 2 schematically illustrates a second configuration example of a light emitting apparatus according to an embodiment.

As compared with the configuration of the light emitting apparatus according to the first configuration example (FIG. 1), only a portion of the light emitting layer 13 is a light emitter 14 in the light emitting apparatus according to the second configuration example. This causes a cross-sectional area in a vertical direction of the light emitting layer 13 and the first crystalline layer 11 to be larger than a cross-sectional area in the vertical direction of the light emitter 14 so that a point light source is formed.

Other configurations and workings may be substantially similar to those of the light emitting apparatus according to the above-described first configuration example (FIG. 1).

### Third Configuration Example

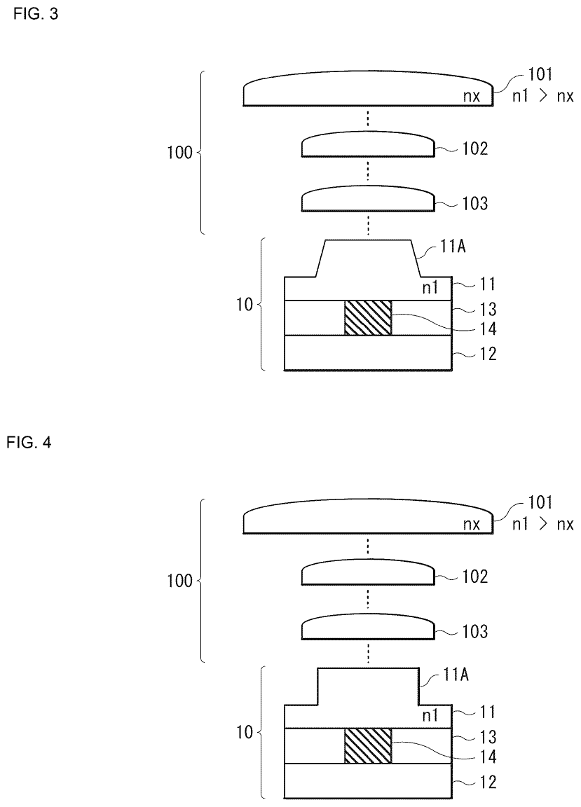

FIG. 3 schematically illustrates a third configuration example of a light emitting apparatus according to an embodiment.

The light emitting apparatus according to the third configuration example is different in a structure of, as the optical functional surface, the surface 11A of the first crystalline layer 11 from the configuration of the light emitting apparatus according to the second configuration example (FIG. 2). In the light emitting apparatus according to the third configuration example, the optical functional surface is in a form of a trapezoidal structure.

Other configurations and workings may be substantially similar to those of the light emitting apparatus according to the above-described first or second configuration example (FIG. 1 or FIG. 2).

### Fourth Configuration Example

FIG. 4 schematically illustrates a fourth configuration example of a light emitting apparatus according to an embodiment.

The light emitting apparatus according to the fourth configuration example is different in a structure of, as the optical functional surface, the surface 11A of the first crystalline layer 11 from the light emitting apparatus according to the second configuration example (FIG. 2). In the light emitting apparatus according to the fourth configuration example, the optical functional surface is in a form of a box lens structure.

Other configurations and workings may be substantially similar to those of the light emitting apparatus according to the above-described first or second configuration example (FIG. 1 or FIG. 2).

### Fifth Configuration Example

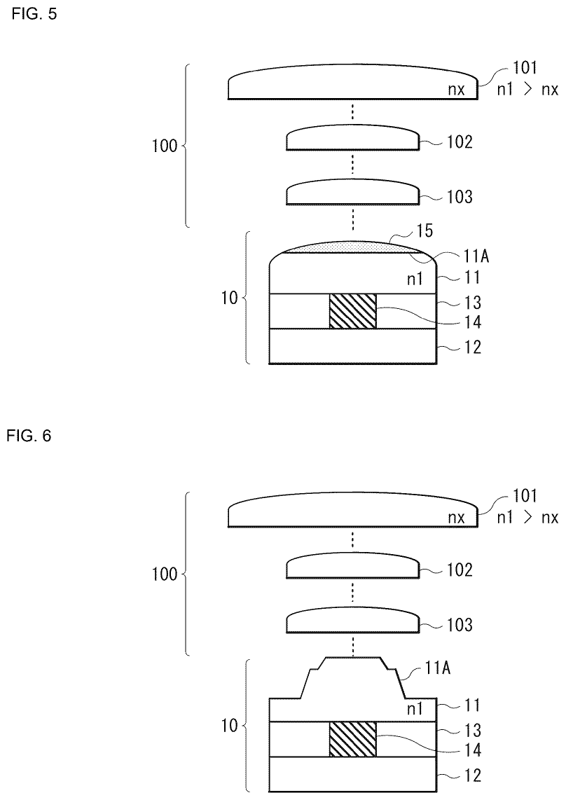

FIG. 5 schematically illustrates a fifth configuration example of a light emitting apparatus according to an embodiment.

The light emitting apparatus according to the fifth configuration example is different in a structure of, as the optical functional surface, the surface 11A of the first crystalline layer 11 from the configuration of the light emitting apparatus according to the second configuration example (FIG. 2). In the light emitting apparatus according to the fifth configuration example, an optical material 15 different from the first crystalline layer 11 is added to at least a portion of the light extraction surface (the surface 11A) of the first crystalline layer 11. This causes a whole shape of the first crystalline layer 11 and the optical material 15 to be in a form of a spherical lens structure or an aspheric lens structure.

Other configurations and workings may be substantially similar to those of the light emitting apparatus according to the above-described first or second configuration example (FIG. 1 or FIG. 2).

### Sixth Configuration Example

FIG. 6 schematically illustrates a sixth configuration example of a light emitting apparatus according to an embodiment.

The light emitting apparatus according to the sixth configuration example is different in a structure of, as the optical functional surface, the surface 11A of the first crystalline layer 11 from the configuration of the light emitting apparatus according to the second configuration example (FIG. 2). In the light emitting apparatus according to the sixth configuration example, the optical functional surface is in a form of a multistage lens structure.

Other configurations and workings may be substantially similar to those of the light emitting apparatus according to the above-described first or second configuration example (FIG. 1 or FIG. 2).

### Seventh Configuration Example

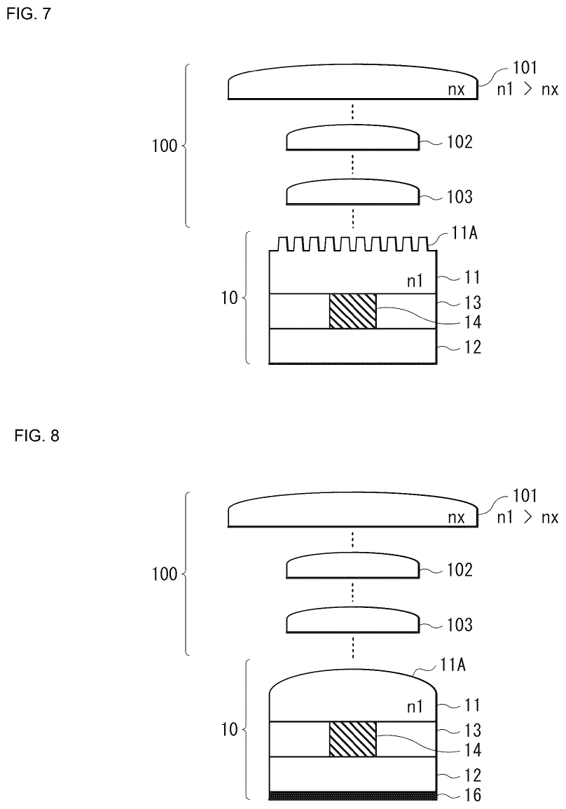

FIG. 7 schematically illustrates a seventh configuration example of a light emitting apparatus according to an embodiment.

The light emitting apparatus according to the seventh configuration example is different in a structure of, as the optical functional surface, the surface 11A of the first crystalline layer 11 from the configuration of the light emitting apparatus according to the second configuration example (FIG. 2). In the light emitting apparatus according to the seventh configuration example, the optical functional surface is in a form of a fine periodic structure. The fine periodic structure may be a Fresnel lens structure, a meta-lens structure, a photonic crystal structure, or a nano-antenna structure.

Other configurations and workings may be substantially similar to those of the light emitting apparatus according to the above-described first or second configuration example (FIG. 1 or FIG. 2).

### Eighth Configuration Example

FIG. 8 schematically illustrates an eighth configuration example of a light emitting apparatus according to an embodiment.

The light emitting apparatus according to the eighth configuration example is different in a structure opposite the light extraction surface from the configuration of the light emitting apparatus according to the second configuration example (FIG. 2). The light emitting apparatus according to the eighth configuration example has a reflective structure opposite the light extraction surface with respect to the light emitting layer 13. The reflective structure may be a structure in which a reflective layer 16 is provided on a back surface of the second crystalline layer 12 (a surface opposite the light extraction surface). The reflective layer 16 may be a highly reflective electrode. The reflective layer 16 may also be a DBR (Distributed Bragg Reflector) layer.

Other configurations and workings may be substantially similar to those of the light emitting apparatus according to the above-described first or second configuration example (FIG. 1 or FIG. 2).

### Ninth Configuration Example

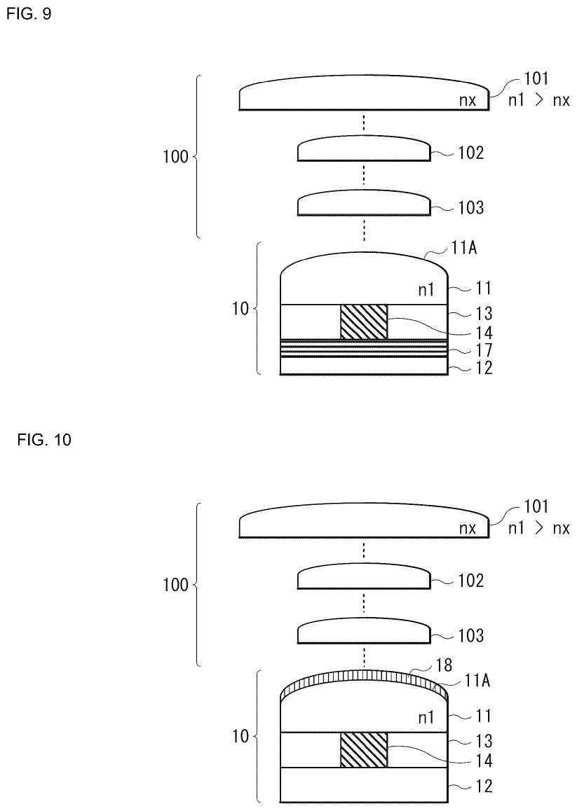

FIG. 9 schematically illustrates a ninth configuration example of a light emitting apparatus according to an embodiment.

The light emitting apparatus according to the ninth configuration example is different in a structure opposite the light extraction surface from the configuration of the light emitting apparatus according to the second configuration example (FIG. 2). The light emitting apparatus according to the ninth configuration example has a reflective structure opposite the light extraction surface with respect to the light emitting layer 13. The reflective structure may be a DBR layer provided in the second crystalline layer 12.

Other configurations and workings may be substantially similar to those of the light emitting apparatus according to the above-described first or second configuration example (FIG. 1 or FIG. 2).

### Tenth Configuration Example

FIG. 10 schematically illustrates a tenth configuration example of a light emitting apparatus according to an embodiment.

The light emitting apparatus according to the tenth configuration example is different in a structure of, as the optical functional surface, the surface 11A of the first crystalline layer 11 from the configuration of the light emitting apparatus according to the second configuration example (FIG. 2). In the light emitting apparatus according to the tenth configuration example, an optical structure 18 is formed by adding an optical material different from the first crystalline layer 11 to at least a portion of the light extraction surface (the surface 11A) of the first crystalline layer 11. The optical structure 18 may be an antireflective film. The optical structure 18 may also be a meta-surface.

Other configurations and workings may be substantially similar to those of the light emitting apparatus according to the above-described first or second configuration example (FIG. 1 or FIG. 2).

### Eleventh Configuration Example

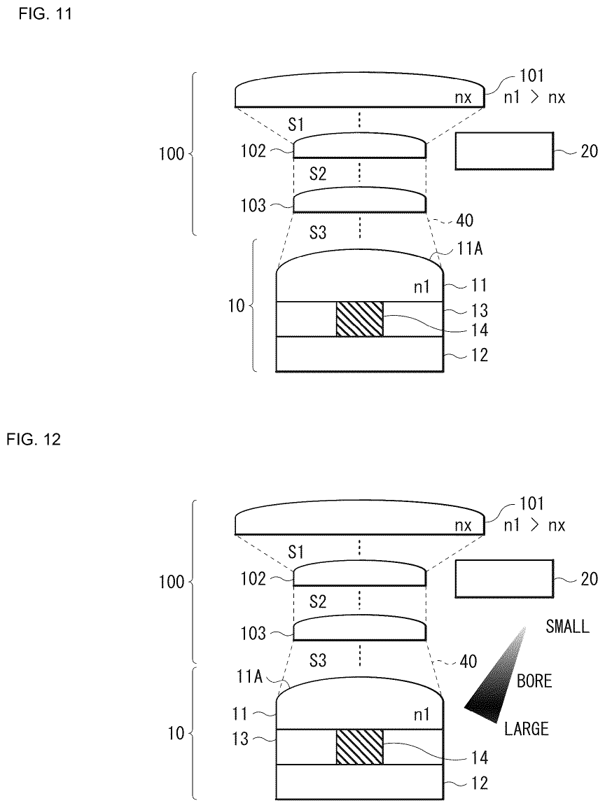

FIG. 11 schematically illustrates an eleventh configuration example of a light emitting apparatus according to an embodiment.

As compared with the configuration of the light emitting apparatus according to the second configuration example (FIG. 2), the light emitting apparatus according to the eleventh configuration example further includes a second light emitting unit 20. For example, in a case where the first light emitting unit 10 is a red LED, the second light emitting unit 20 may be a green LED or a blue LED. Moreover, for example, in a case where the first light emitting unit 10 is a green LED, the second light emitting unit 20 may be a red LED or a blue LED. Moreover, for example, in a case where the first light emitting unit 10 is a blue LED, the second light emitting unit 20 may be a red LED or a green LED.

It should be noted that another at least one light emitting unit (a third light emitting unit, a fourth light emitting unit . . . ) may be disposed in addition to the second light emitting unit 20.

In order to avoid a vertically projected region 40, the second light emitting unit 20 is disposed outside the vertically projected region 40. The vertically projected region 40 is formed by adjacent ones of the optical functional surface of the first light emitting unit 10 and the at least one optical member of the optical unit 100. It should be noted that although FIG. 11 illustrates an example where the first light emitting unit 10 and the second light emitting unit 20 are disposed at different positions in the vertical direction, the first light emitting unit 10 and the second light emitting unit 20 may be disposed at the same position in the vertical direction (at the same level).

It should be noted that the optical unit 100 may include, as the optical members, a plurality of optical members arranged in the vertical direction. In this case, out of areas of at least two vertically projected regions 40 formed by adjacent ones of the optical functional surface of the first light emitting unit 10 and the plurality of optical members, the area of the vertically projected region 40 formed at the farthest position from the first light emitting unit 10 may be the largest. For example, with the assumption that areas (vertically projected areas) of the vertically projected regions 40 formed in a case where the first optical member 101, the second optical member 102, and the third optical member 103 are provided as the optical members in sequence from the farthest position from the first light emitting unit 10 are denoted by S1, S2, and S3 as illustrated in FIG. 11, the vertically projected area S1 formed at the farthest position from the first light emitting unit 10 is the largest.

Other configurations and workings may be substantially similar to those of the light emitting apparatus according to the above-described first or second configuration example (FIG. 1 or FIG. 2).

### Twelfth Configuration Example

FIG. 12 schematically illustrates a twelfth configuration example of a light emitting apparatus according to an embodiment.

The light emitting apparatus according to the twelfth configuration example may further include the second light emitting unit 20 similarly to the light emitting apparatus according to the eleventh configuration example (FIG. 11). A bore of the first light emitting unit 10 may be larger than a bore of the second light emitting unit 20. It should be noted that in a case where another at least one light emitting unit (the third light emitting unit, the fourth light emitting unit, . . . ) is disposed in addition to the second light emitting unit 20, the light emitting unit more distant from the first light emitting unit 10 may have a smaller bore.

Other configurations and workings may be substantially similar to those of the light emitting apparatus according to the above-described eleventh configuration example (FIG. 11).

### Thirteenth Configuration Example

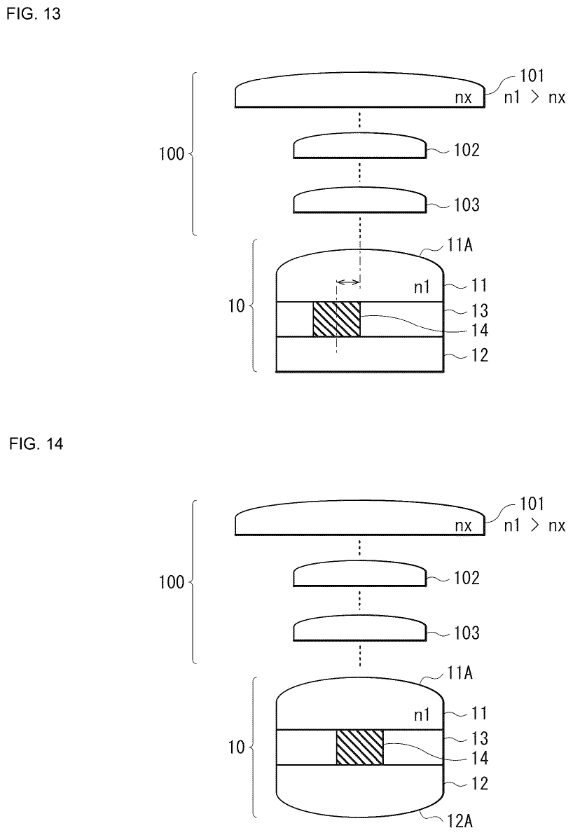

FIG. 13 schematically illustrates a thirteenth configuration example of a light emitting apparatus according to an embodiment.

The light emitting apparatus according to the thirteenth configuration example is different in a structure of the light emitting layer 13 from the configuration of the light emitting apparatus according to the second configuration example (FIG. 2). In the light emitting apparatus according to the thirteenth configuration example, a center position of the light emitter 14 in the light emitting layer 13 is offset with respect to a center position of the optical functional surface of the first crystalline layer 11.

Other configurations and workings may be substantially similar to those of the light emitting apparatus according to the above-described first or second configuration example (FIG. 1 or FIG. 2).

### Fourteenth Configuration Example

FIG. 14 schematically illustrates a fourteenth configuration example of a light emitting apparatus according to an embodiment.

The light emitting apparatus according to the fourteenth configuration example is different in a structure opposite the light extraction surface from the configuration of the light emitting apparatus according to the second configuration example (FIG. 2). The light emitting apparatus according to the fourteenth configuration example has a reflective structure opposite the light extraction surface with respect to the light emitting layer 13. In the light emitting apparatus according to the fourteenth configuration example, a back surface (a surface opposite the light extraction surface) of the second crystalline layer 12 is, as the reflective structure, in a form of a concave mirror.

Other configurations and workings may be substantially similar to those of the light emitting apparatus according to the above-described first or second configuration example (FIG. 1 or FIG. 2).

### Fifteenth Configuration Example

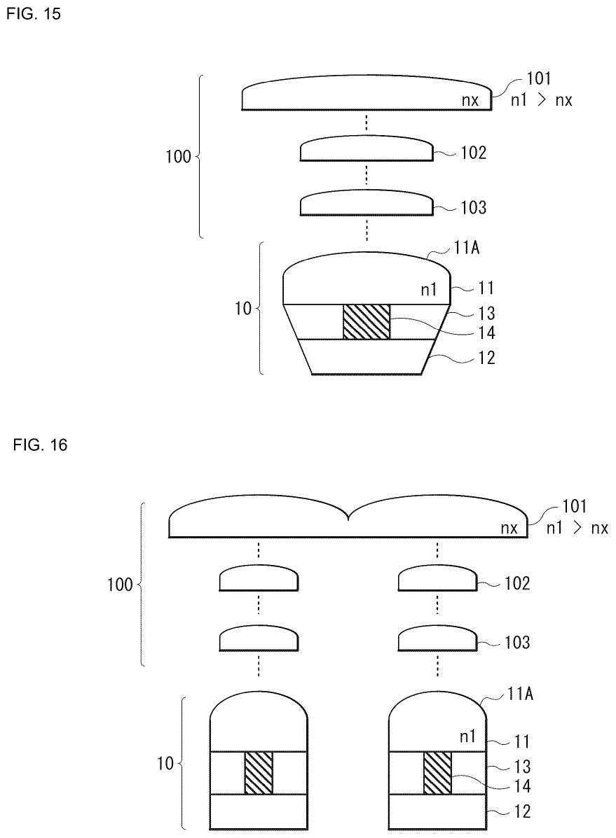

FIG. 15 schematically illustrates a fifteenth configuration example of a light emitting apparatus according to an embodiment.

The light emitting apparatus according to the fifth configuration example is different in structures of the second crystalline layer 12 and the light emitting layer 13 from the configuration of the light emitting apparatus according to the second configuration example (FIG. 2). The light emitting apparatus according to the fifteenth configuration example has a structure where side surfaces of the second crystalline layer 12 and the light emitting layer 13 are slanted (obliquely etched).

Other configurations and workings may be substantially similar to those of the light emitting apparatus according to the above-described first or second configuration example (FIG. 1 or FIG. 2).

### Sixteenth Configuration Example

FIG. 16 schematically illustrates a sixteenth configuration example of a light emitting apparatus according to an embodiment.

A plurality of light emitting apparatuses according to one of the above-described first to fifteenth configuration examples (FIG. 1 to FIG. 15) may be disposed in array. FIG. 16 illustrates a configuration example of a case where a plurality of light emitting apparatuses according to the second configuration example (FIG. 2) is disposed in array. In a case where the plurality of light emitting apparatuses is disposed in array, adjacent ones of the optical members forming the optical unit 100 may be joined to each other. In a case where the optical unit 100 includes the plurality of optical members, adjacent ones of the optical members including the same material may be joined to each other. FIG. 16 illustrates a configuration example where adjacent ones of the first optical members 101 disposed at the farthest position from the first light emitting units 10 are joined to each other.

Other configurations and workings may be substantially similar to those of the light emitting apparatuses according to the above-described first to fifteenth configuration examples (FIG. 1 to FIG. 15).

### Seventeenth Configuration Example

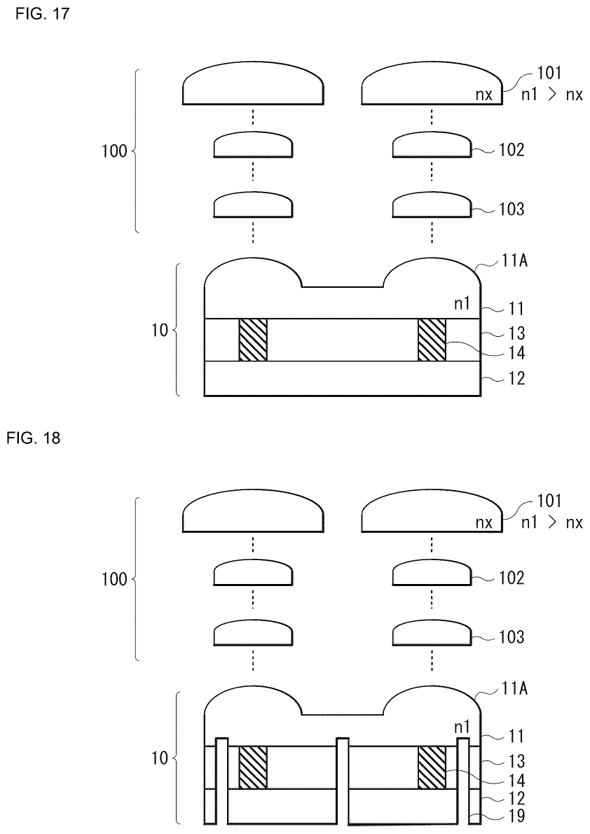

FIG. 17 schematically illustrates a seventeenth configuration example of a light emitting apparatus according to an embodiment.

A plurality of light emitting apparatuses according to one of the above-described first to fifteenth configuration examples (FIG. 1 to FIG. 15) may be disposed in array. FIG. 17 illustrates a configuration example of a case where a plurality of light emitting apparatuses according to the second configuration example (FIG. 2) is disposed in array. In a case where the plurality of light emitting apparatuses is disposed in array, portions of adjacent two of the first light emitting units 10 may be at least partly joined to each other. The portions include the same material. FIG. 17 illustrates a configuration example where the respective first crystalline layers 11, second crystalline layers 12, and light emitting layers 13 of adjacent ones of the first light emitting units 10 are at least partly joined to each other.

Other configurations and workings may be substantially similar to those of the light emitting apparatuses according to the above-described first to fifteenth configuration examples (FIG. 1 to FIG. 15).

### Eighteenth Configuration Example

FIG. 18 schematically illustrates an eighteenth configuration example of a light emitting apparatus according to an embodiment.

A plurality of light emitting apparatuses according to one of the above-described first to fifteenth configuration examples (FIG. 1 to FIG. 15) may be disposed in array. FIG. 18 illustrates a configuration example of a case where a plurality of light emitting apparatuses according to the second configuration example (FIG. 2) is disposed in array. In a case where the plurality of light emitting apparatuses is disposed in array, portions of adjacent two of the first light emitting units 10 may be at least partly joined to each other. The portions include the same material. FIG. 18 illustrates a configuration example where the respective first crystalline layers 11, second crystalline layers 12, and light emitting layers 13 of adjacent ones of the first light emitting units 10 are at least partly joined to each other. The configuration example in FIG. 18 illustrates a configuration example where a separating layer 19 is formed in at least a portion between the respective first crystalline layers 11, between the respective second crystalline layers 12, and between the respective light emitting layers 13 of the adjacent first light emitting units 10. The separating layer 19 may be formed through a manufacturing process.

Other configurations and workings may be substantially similar to those of the light emitting apparatuses according to the above-described first to fifteenth configuration examples (FIG. 1 to FIG. 15).

### Nineteenth Configuration Example

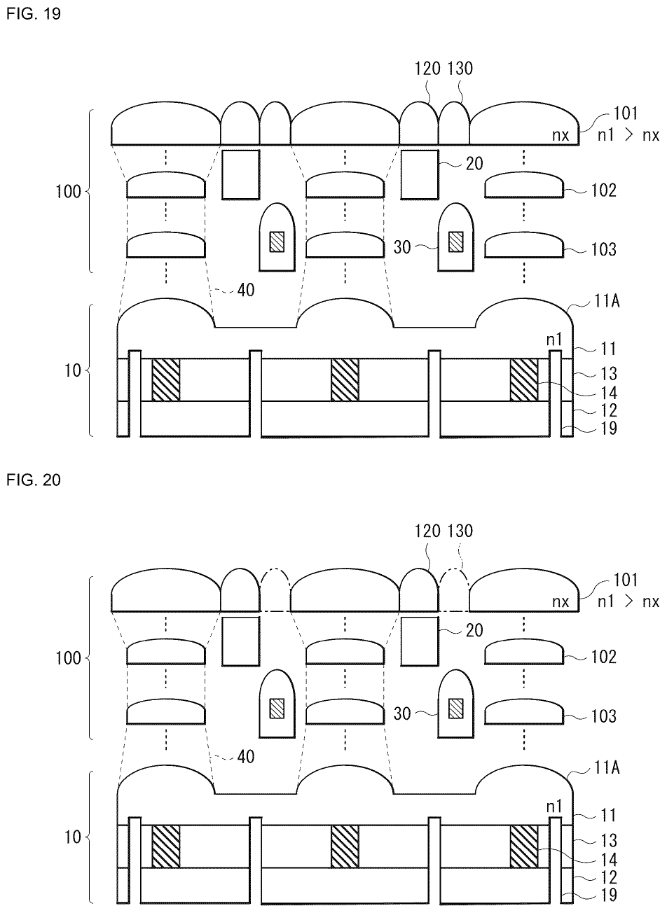

FIG. 19 schematically illustrates a nineteenth configuration example of a light emitting apparatus according to an embodiment.

As compared with the configuration of the light emitting apparatus according to the eighteenth configuration example (FIG. 18), the light emitting apparatus according to the nineteenth configuration example further includes the second light emitting unit 20 and a third light emitting unit 30. Moreover, the light emitting apparatus according to the nineteenth configuration example further includes an optical unit 120 opposed to a light extraction surface side of the second light emitting unit 20 and an optical unit 130 opposed to a light extraction surface side of the third light emitting unit 30. The optical unit 120 and the optical unit 130 each include at least one optical member having a light collecting effect.

In order to avoid the vertically projected region 40, the second light emitting unit 20 and the third light emitting unit 30 are disposed outside the vertically projected region 40. The vertically projected region 40 is formed by adjacent ones of the optical functional surface of the first light emitting unit 10 and the at least one optical member of the optical unit 100.

The first light emitting unit 10, the second light emitting unit 20, and the third light emitting unit 30 may be LEDs that emit light with different colors from each other. For example, the first light emitting unit 10, the second light emitting unit 20, and the third light emitting unit 30 may each be any one of a red LED, a green LED, and a blue LED.

Moreover, the second light emitting unit 20, the third light emitting unit 30, or both may have a light extraction surface that at least partly serves as an optical functional surface having a light collecting effect as the first light emitting unit 10. FIG. 19 illustrates a configuration example where the light extraction surface of the third light emitting unit 30 is the optical functional surface having the light collecting effect.

Out of the respective bores of the first light emitting unit 10, the second light emitting unit 20, and the third light emitting unit 30, the bore of the first light emitting unit 10 may be the largest. Moreover, out of the second light emitting unit 20 and the third light emitting unit 30, the light emitting unit that is more distant from the first light emitting unit 10 may have a smaller bore.

Other configurations and workings may be substantially similar to those of the light emitting apparatus according to the above-described eighteenth configuration example (FIG. 18).

### Twentieth Configuration Example

FIG. 20 schematically illustrates a twentieth configuration example of a light emitting apparatus according to an embodiment.

As compared with the configuration of the light emitting apparatus according to the nineteenth configuration example (FIG. 19), one of the optical unit 120 and the optical unit 130 is omitted from a configuration of the light emitting apparatus according to the twentieth configuration example. FIG. 20 illustrates an example where the optical unit 130 is omitted from the configuration.

Other configurations and workings may be substantially similar to those of the light emitting apparatus according to the above-described nineteenth configuration example (FIG. 19).

### Twenty-First Configuration Example

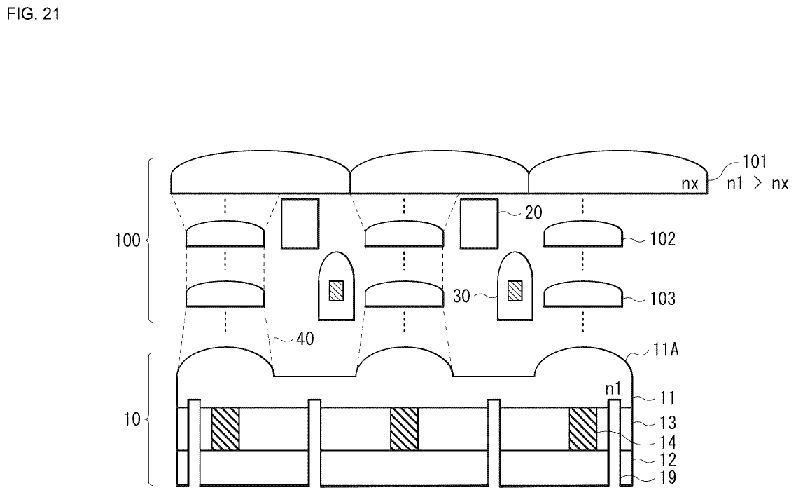

FIG. 21 schematically illustrates a twenty-first configuration example of a light emitting apparatus according to an embodiment.

FIG. 21 illustrates, as a light emitting apparatus according to the twenty-first configuration example, a configuration example where the single optical unit 100 serves as both the optical unit 120 and the optical unit 130 as compared with the configuration the light emitting apparatus according to the nineteenth configuration example (FIG. 19). In the light emitting apparatus according to the twenty-first configuration example, the single optical unit 100 is opposed to the first light emitting unit 10, the second light emitting unit 20, and the third light emitting unit 30 and has a light collecting effect on light from the first light emitting unit 10, the second light emitting unit 20, and the third light emitting unit 30.

Other configurations and workings may be substantially similar to those of the light emitting apparatus according to the above-described nineteenth configuration example (FIG. 19).

### Twenty-Second Configuration Example

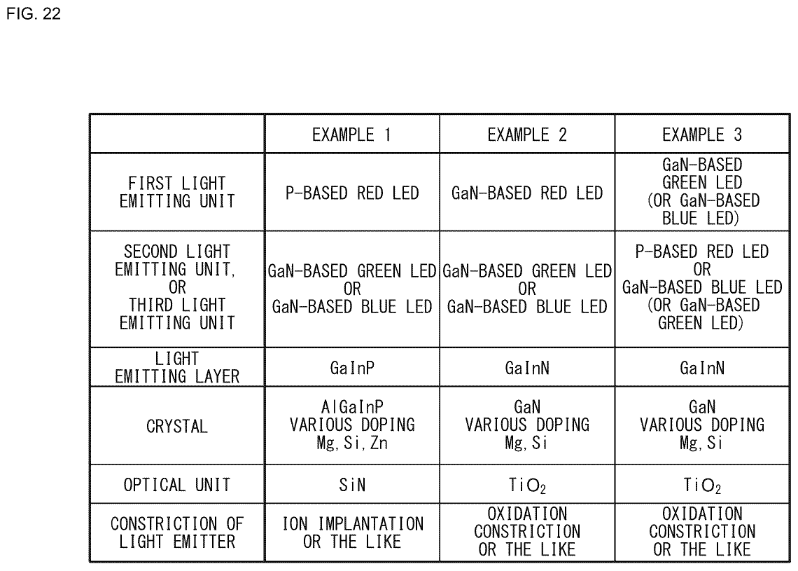

FIG. 22 illustrates an example of respective specific materials of units of the light emitting apparatuses according to the nineteenth to twenty-first configuration examples.

In the nineteenth to twenty-first configuration examples, the first light emitting unit 10, the second light emitting unit 20, and the third light emitting unit 30 may each be any one of a red LED, a green LED, and a blue LED.

For example, as indicated under Example 1 in FIG. 22, the first light emitting unit 10 may be a P-based red LED. In this case, the second light emitting unit 20 or the third light emitting unit 30 may be a GaN-based green LED or a GaN-based blue LED. Moreover, in this case, the light emitting layer 13 may be a GaInP layer. The first crystalline layer 11 and the second crystalline layer 12 may be an AlGaInP layer doped with Mg, Si, Zn, or the like. The optical unit 100 may be SiN. The light emitter 14 may be constricted by ion implantation or the like. In addition to the above, the light emitter 14 may be constricted by oxidation, physical etching, or the like.

Moreover, for example, as indicated under Example 2 in FIG. 22, the first light emitting unit 10 may be a GaN-based red LED. In this case, the second light emitting unit 20 or the third light emitting unit 30 may be a GaN-based green LED or a GaN-based blue LED. Moreover, the light emitting layer 13 may be a GaInN layer in this case. The first crystalline layer 11 and the second crystalline layer 12 may be a GaN layer doped with Mg, Si, or the like. The optical unit 100 may be TiO₂. The light emitter 14 may be constricted by oxidation or the like. In addition to the above, the light emitter 14 may be constricted by ion implantation, physical etching, or the like.

Moreover, for example, as indicated under Example 3 in FIG. 22, the first light emitting unit 10 may be a GaN-based green LED (or a GaN-based blue LED). In this case, the second light emitting unit 20 or the third light emitting unit 30 may be a P-based red LED or a GaN-based blue LED (or a GaN-based green LED). Moreover, the light emitting layer 13 may be a GaInN layer in this case. The first crystalline layer 11 and the second crystalline layer 12 may be a GaN layer doped with Mg, Si, or the like. The optical unit 100 may be TiO₂. The light emitter 14 may be constricted by oxidation or the like. In addition to the above, the light emitter 14 may be constricted by ion implantation, physical etching, or the like.

### 1.2 Workings and Effects

As described above, in the light emitting apparatus according to an embodiment, at least a portion of the light extraction surface of the first crystalline layer 11 has a light collecting effect and the optical unit 100 opposed to the light extraction surface side of the first light emitting unit 10 has a light collecting effect. This makes it possible to improve the light extraction efficiency. Moreover, in a case where the light emitting apparatus according to an embodiment is arrayed, it is possible to narrow an arrangement pitch of the first light emitting units 10.

Moreover, the light emitting apparatus according to an embodiment has a considerably high light-harvesting structure, which enables an efficient waveguide of light from a lower tier to an upper tier even though the structure includes a plurality of LEDs in two or more tiers that is three-dimensionally disposed.

Moreover, the light emitting apparatus according to an embodiment makes it possible to implement a high-efficiency Native-type light emitting apparatus with RGB LEDs in, for example, a micro LED display for AR.

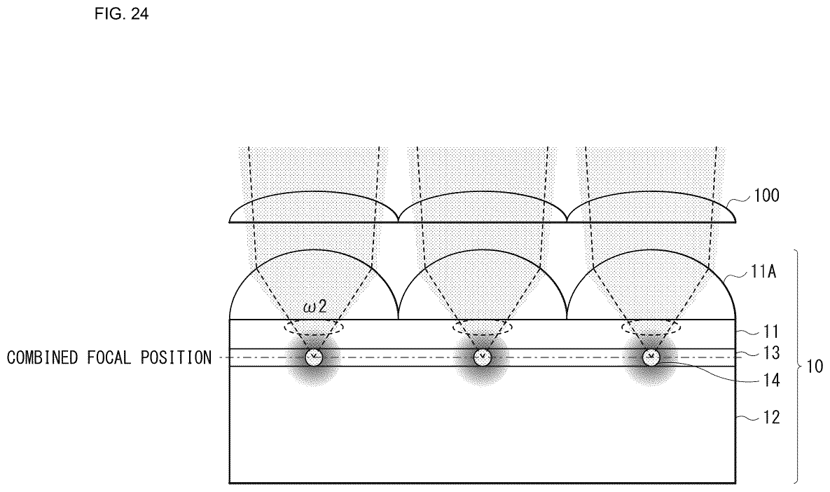

FIG. 23 schematically illustrates a configuration example of a light emitting apparatus according to a comparative example. Moreover, FIG. 24 schematically illustrates a configuration example of a light emitting apparatus according to an embodiment.

The light emitting apparatus according to the comparative example illustrated in FIG. 23 includes an optical unit 200 having a light collecting effect disposed on the light extraction surface side of the first light emitting unit 10. In the light emitting apparatus according to the comparative example, the light extraction surface (the surface 11A of the first crystalline layer 11) of the first light emitting unit 10 is a flat surface. For the light emitting apparatus according to the comparative example, an increase in effective bore of the first light emitting unit 10 causes the focal position to be offset with respect to the light emitter 14 with a light-harvesting efficiency deteriorated.

In contrast, in the light emitting apparatus according to an embodiment illustrated in FIG. 24, an effect of a combined lens provided by the optical functional surface of the first light emitting unit 10 and the optical unit 100 makes it possible to shorten the focal length. This makes it possible to match the combined focal position through the optical functional surface of the first light emitting unit 10 and the optical unit 100 with respect to the light emitter 14 to improve light-harvesting efficiency (in FIG. 23 and FIG. 24, ω1<ω2).

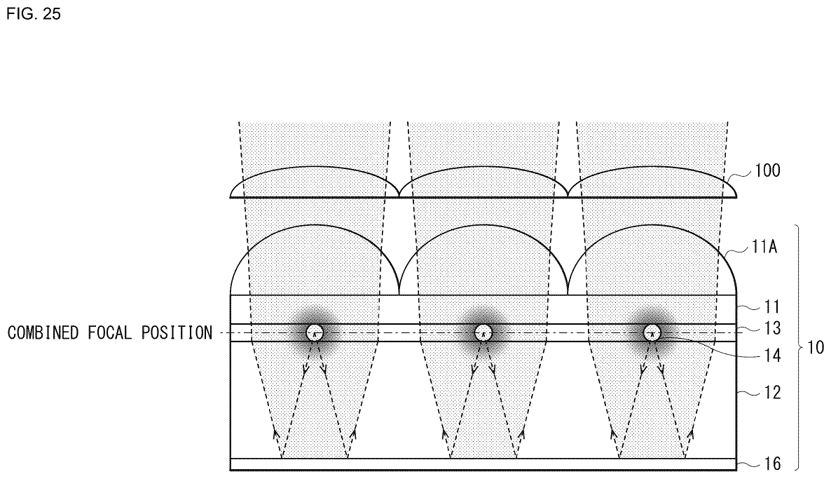

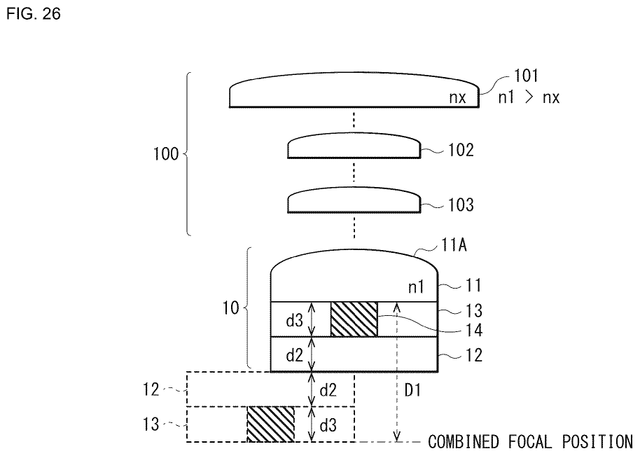

It should be noted that in a case where the reflective layer 16 of the first light emitting unit 10 is, for example, opposite the light extraction surface, it may be understood that the focal length is shortened as returned by the reflective layer 16. FIG. 25 schematically illustrates a configuration example of the light emitting apparatus according to an embodiment. FIG. 26 is a diagram of assistance in explanation about the combined focal position of the optical functional surface of the first light emitting unit 10 and the optical unit 100 in the configuration example illustrated in FIG. 25.

Here, it is assumed that D1 denotes a distance from an interface between the first crystalline layer 11 and the light emitting layer 13 to the combined focal position of the optical functional surface of the first light emitting unit 10 and the optical unit 100 as illustrated in FIG. 26. Moreover, assuming that d2 denotes a thickness of the second crystalline layer 12 and d3 denotes a thickness of the light emitting layer 13, a position of (d2×2)+(d3×2) from the interface between the first crystalline layer 11 and the light emitting layer 13 becomes the combined focal position in the configuration example in FIG. 25 as illustrated in FIG. 26.

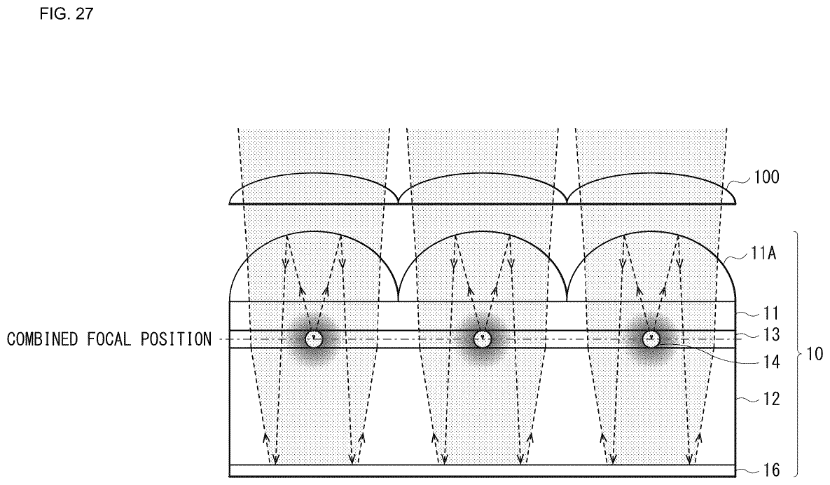

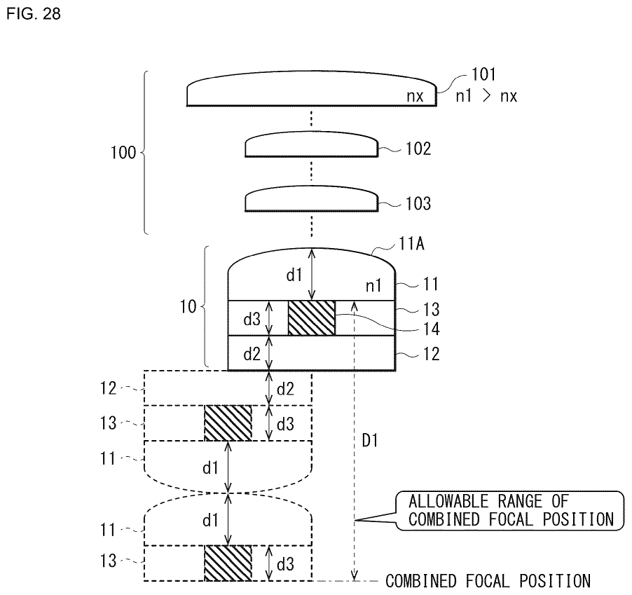

Moreover, FIG. 27 schematically illustrates a configuration example in which, for example, an internal reflection by the light extraction surface (the surface 11A of the first crystalline layer 11) in the first light emitting unit 10 is taken into consideration. FIG. 28 is a diagram of assistance in explanation about the combined focal position of the optical functional surface of the first light emitting unit 10 and the optical unit 100 in the configuration example illustrated in FIG. 27

The light emitting apparatus according to an embodiment may be configured to satisfy

$$D 1 \leq ( d 1 \times 2 ) + ( d 2 \times 2 ) + ( d 3 \times 3 )$$

where D1 denotes the distance from the interface between the first crystalline layer 11 and the light emitting layer 13 to the combined focal position of the optical functional surface of the first light emitting unit 10 and the optical unit 100, d1 denotes the thickness of the first crystalline layer 11, d2 denotes the thickness of the second crystalline layer 12, and d3 denotes the thickness of the light emitting layer 13.

That is to say, the combined focal position of the optical functional surface of the first light emitting unit 10 and the optical unit 100 may fall within, in an opposite direction to the light extraction surface, a range of (d1×2)+(d2×2)+(d3×3) from the interface between the first crystalline layer 11 and the light emitting layer 13.

It should be noted that the effects described herein are merely examples and non-limiting and other effects are possible. The same applies to the effects of other embodiments hereinbelow.

### 2. Other Embodiments

The present disclosure may be implemented with a variety of modifications without limitation to the explanation of the above-described embodiment.

For example, the present technology may adopt the following configuration.

According to the present technology with the following configuration, at least a portion of a light extraction surface of a first crystalline layer has a light collecting effect and an optical unit opposed to a light extraction surface side of a first light emitting unit has a light collecting effect. This makes it possible to improve the light extraction efficiency.

(1)

A light emitting apparatus including:
a first light emitting unit including: a first crystalline layer provided on a light extraction surface side; a second crystalline layer; and a light emitting layer disposed between the first crystalline layer and the second crystalline layer, at least a portion of a light extraction surface of the first crystalline layer being an optical functional surface, the optical functional surface having a light collecting effect; and
an optical unit including at least one optical member having a light collecting effect, the optical unit being opposed to the light extraction surface side of the first light emitting unit.
   (2)

The light emitting apparatus according to (1), in which
the optical functional surface includes a spherical lens structure, an aspheric lens structure, a box lens structure, or a fine periodic structure.
   (3)

The light emitting apparatus according to (2), in which
the fine periodic structure includes a Fresnel lens structure, a meta-lens structure, a photonic crystal structure, or a nano-antenna structure.
   (4)

The light emitting apparatus according to any one of (1) to (3), in which
an optical material different from the first crystalline layer is added to at least a portion of the light extraction surface of the first crystalline layer.
   (5)

The light emitting apparatus according to (4), in which
the optical material includes an antireflective film.
   (6)

The light emitting apparatus according to any one of (1) to (5), in which
the light emitting layer includes a light emitter, and
a cross-sectional area in a vertical direction of the light emitting layer and the first crystalline layer is larger than a cross-sectional area in the vertical direction of the light emitter.
   (7)

The light emitting apparatus according to any one of (1) to (6), in which

$$D 1 \leq ( d 1 \times 2 ) + ( d 2 \times 2 ) + ( d 3 \times 3 ) is satisfied ,$$

where
D1 denotes a distance from an interface between the first crystalline layer and the light emitting layer to a combined focal position of the optical functional surface of the first light emitting unit and the optical unit,
d1 denotes a thickness of the first crystalline layer,
d2 denotes a thickness of the second crystalline layer, and
d3 denotes a thickness of the light emitting layer.
   (8)

The light emitting apparatus according to any one of (1) to (7), in which
a reflective structure is provided opposite the light extraction surface with respect to the light emitting layer.
   (9)

The light emitting apparatus according to (8), in which
the reflective structure includes a DBR (Distributed Bragg Reflector) layer in the second crystalline layer.
   (10)

The light emitting apparatus according to (8), in which
the reflective structure is provided in a surface of the second crystalline layer opposite the light extraction surface.
   (11)

The light emitting apparatus according to (10), in which
the reflective structure includes a DBR (Distributed Bragg Reflector) layer.
   (12)

The light emitting apparatus according to any one of (1) to (11), further including
a second light emitting unit outside a vertically projected region, the vertically projected region being formed by adjacent ones of the optical functional surface of the first light emitting unit and the at least one optical member.
   (13)

The light emitting apparatus according to (12), in which
the optical unit includes, as the optical member, a plurality of optical members arranged in a vertical direction, and
out of areas of at least two vertically projected regions formed by adjacent ones of the optical functional surface of the first light emitting unit and the plurality of optical members, the area of the vertically projected region formed at a position farthest from the first light emitting unit is largest.
   (14)

The light emitting apparatus according to (12) or (13), in which
a bore of the first light emitting unit is larger than a bore of the second light emitting unit.
   (15)

The light emitting apparatus according to any one of (1) to (14), in which
the first crystalline layer and the second crystalline layer include a semiconductor layer.
   (16)

The light emitting apparatus according to any one of (1) to (15), including a plurality of the first light emitting units,
in which respective portions of adjacent two of the first light emitting units are at least partly joined to each other, the respective portions including a same material.
   (17)

The light emitting apparatus according to (16), in which
respective light emitting layers of the adjacent two of the first light emitting units are at least partly joined to each other.
   (18)

The light emitting apparatus according to (16) to (17), in which
respective first crystalline layers and second crystalline layers of the adjacent two of the first light emitting units are at least partly joined to each other.

The present application claims the benefit of Japanese Priority Patent Application JP 2022-118567 filed with the Japan Patent Office on Jul. 26, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light emitting apparatus comprising:
a first light emitting unit including: a first crystalline layer provided on a light extraction surface side; a second crystalline layer; and a light emitting layer disposed between the first crystalline layer and the second crystalline layer, at least a portion of a light extraction surface of the first crystalline layer being an optical functional surface, the optical functional surface having a light collecting effect; and
an optical unit including at least one optical member having a light collecting effect, the optical unit being opposed to the light extraction surface side of the first light emitting unit.

2. The light emitting apparatus according to claim 1, wherein
the optical functional surface includes a spherical lens structure, an aspheric lens structure, a box lens structure, or a fine periodic structure.

3. The light emitting apparatus according to claim 2, wherein
the fine periodic structure includes a Fresnel lens structure, a meta-lens structure, a photonic crystal structure, or a nano-antenna structure.

4. The light emitting apparatus according to claim 1, wherein
an optical material different from the first crystalline layer is added to at least a portion of the light extraction surface of the first crystalline layer.

5. The light emitting apparatus according to claim 4, wherein
the optical material includes an antireflective film.

6. The light emitting apparatus according to claim 1, wherein
the light emitting layer includes a light emitter, and
a cross-sectional area in a vertical direction of the light emitting layer and the first crystalline layer is larger than a cross-sectional area in the vertical direction of the light emitter.

7. The light emitting apparatus according to claim 1, wherein
$$D 1 \leq ( d 1 \times 2 ) + ( d 2 \times 2 ) + ( d 3 \times 3 ) is satisfied ,$$
where
D1 denotes a distance from an interface between the first crystalline layer and the light emitting layer to a combined focal position of the optical functional surface of the first light emitting unit and the optical unit,
d1 denotes a thickness of the first crystalline layer,
d2 denotes a thickness of the second crystalline layer, and
d3 denotes a thickness of the light emitting layer.

8. The light emitting apparatus according to claim 1, wherein
a reflective structure is provided opposite the light extraction surface with respect to the light emitting layer.

9. The light emitting apparatus according to claim 8, wherein
the reflective structure includes a DBR (Distributed Bragg Reflector) layer in the second crystalline layer.

10. The light emitting apparatus according to claim 8, wherein
the reflective structure is provided in a surface of the second crystalline layer opposite the light extraction surface.

11. The light emitting apparatus according to claim 10, wherein
the reflective structure includes a DBR (Distributed Bragg Reflector) layer.

12. The light emitting apparatus according to claim 1, further comprising
a second light emitting unit outside a vertically projected region, the vertically projected region being formed by adjacent ones of the optical functional surface of the first light emitting unit and the at least one optical member.

13. The light emitting apparatus according to claim 12, wherein
the optical unit includes, as the optical member, a plurality of optical members arranged in a vertical direction, and
out of areas of at least two vertically projected regions formed by adjacent ones of the optical functional surface of the first light emitting unit and the plurality of optical members, the area of the vertically projected region formed at a position farthest from the first light emitting unit is largest.

14. The light emitting apparatus according to claim 12, wherein
a bore of the first light emitting unit is larger than a bore of the second light emitting unit.

15. The light emitting apparatus according to claim 1, wherein
the first crystalline layer and the second crystalline layer include a semiconductor layer.

16. The light emitting apparatus according to claim 1, comprising a plurality of the first light emitting units,
wherein respective portions of adjacent two of the first light emitting units are at least partly joined to each other, the respective portions including a same material.

17. The light emitting apparatus according to claim 16, wherein
respective light emitting layers of the adjacent two of the first light emitting units are at least partly joined to each other.

18. The light emitting apparatus according to claim 16, wherein
respective first crystalline layers and second crystalline layers of the adjacent two of the first light emitting units are at least partly joined to each other.
